(19) United States
(12) Patent Application Publication
(10) Pub. No.: US 2026/0186075 A1
(43) Pub. Date: Jul. 2, 2026

(54) PROCESSING APPARATUS

(71) Applicant: Sony Interactive Entertainment Inc., Tokyo (JP)

(72) Inventor: Yusuke Onishi, Tokyo (JP)

(21) Appl. No.: 19/546,960

(22) Filed: Feb. 23, 2026

Related U.S. Application Data
(63) Continuation of application No. PCT/JP2023/031606, filed on Aug. 30, 2023.

(51) Int. Cl. G01R 31/56; G01R 21/133

(52) U.S. Cl. CPC G01R 31/56; G01R 21/133

(57) ABSTRACT

A processing apparatus 20 including a function for estimating a status of an electronic equipment 10 for executing an application. An acquisition unit 42 acquires a generated amount of power generated via the use of energy produced by operating the electronic equipment 10. An estimation unit 44 estimates the status of the electronic equipment 10 based on the generated amount of power acquired.

### CROSS-REFERENCE TO RELATED APPLICATIONS

This application is a Continuation of International Application No. PCT/JP2023/031606, having an International Filing Date of Aug. 30, 2023. This disclosure of the prior application is considered part of the disclosure of this application.

### FIELD

The present disclosure relates to art for estimating the status of electronic equipment for running an application such as a game.

### BACKGROUND

Electronic equipment produces various types of energy when executing an application such as a game.

### SUMMARY

The present disclosure proposes art for estimating the status of an electronic equipment via the use of energy produced by operating the electronic equipment.

A processing apparatus for estimating a status of an electronic equipment for executing an application, wherein the processing apparatus according to an aspect of the present disclosure includes: an acquisition unit for acquiring a generated amount of power generated via the use of energy produced by operating the electronic equipment, and an estimation unit for estimating the status of the electronic equipment based on the generated amount of power acquired.

### BRIEF DESCRIPTION OF THE DRAWINGS

FIG. 1 is a diagram illustrating a configuration example of an information processing system of one embodiment.

FIG. 2 is a diagram illustrating functional blocks of a processing apparatus.

FIG. 3 is a diagram illustrating a display example of generated amounts of power.

FIG. 4 is a diagram illustrating an example of a warning display.

### DETAILED DESCRIPTION

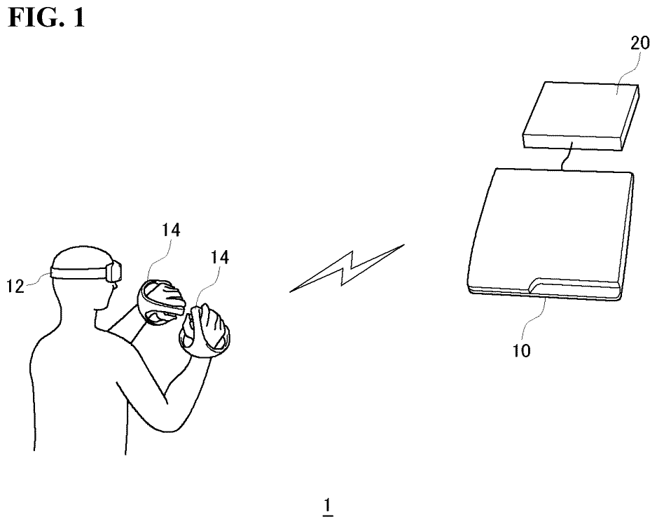

FIG. 1 illustrates a configuration example of an information processing system 1 of an embodiment. The information processing system 1 includes: an electronic equipment 10 for running an application such as a game, a head-mounted display (HMD) 12 worn on the head of a user, an input device 14 held in the hands of and operated using the fingers of the user, and a processing apparatus 20 for estimating a status of the electronic equipment 10. The electronic equipment 10 may be a gaming apparatus for executing a game program based on operation information obtained by the user operating the input device 14, generating image and sound data for the game, and supplying the data to the HMD 12. The electronic equipment 10 and the HMD 12 may be connected using a known wireless communication protocol, or may be connected using a cable.

The HMD 12 is a display apparatus for displaying an image on a display panel located in front of the eyes when worn on the head of the user, and is also referred to as a VR headset. The HMD 12 separately displays an image for the left eye on a left eye display panel and an image for the right eye on a right eye display panel, respectively, and these images form a parallax image seen from left and right viewpoints, thereby realizing stereoscopic vision.

The electronic equipment 10 and the input device 14 may be connected using a known wireless communication protocol, or may be connected using a cable. The input device 14 includes a plurality of operating members such as operation buttons, and the user operates the operating members using their fingers while gripping the input device 14.

In the information processing system 1 of the embodiment, the processing apparatus 20 has a power generation function, and includes a power generating element for generating power via the use of energy produced by operating the electronic equipment 10. The processing apparatus 20 may include a plurality of power generating elements that use different power generation methods. The processing apparatus 20 includes a function of estimating a status of the electronic equipment 10 based on a generated amount of power of the power generating element.

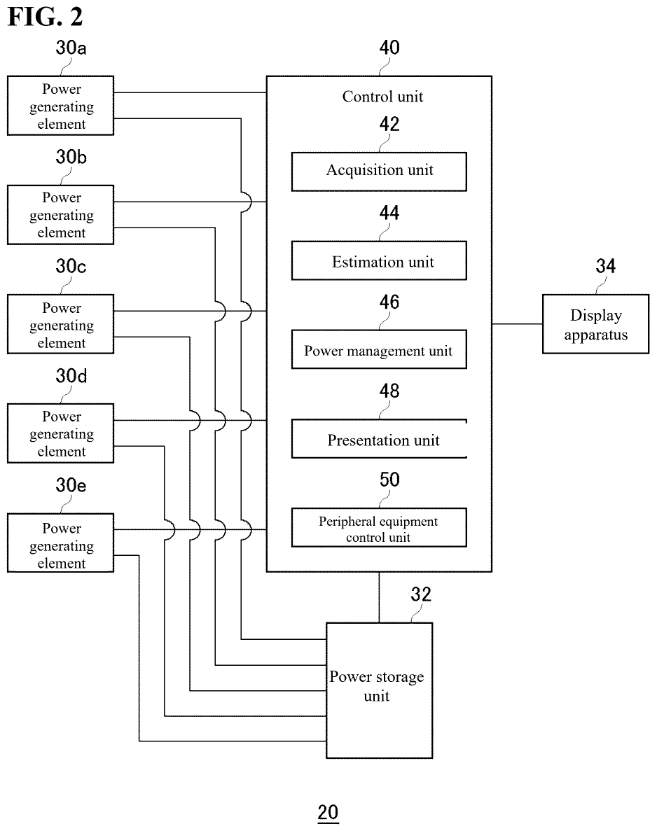

FIG. 2 illustrates functional blocks of the processing apparatus 20. The processing apparatus 20 includes a plurality of power generating elements 30a, 30b, 30c, 30d, and 30e, a power storage unit 32, a display apparatus 34, and a control unit 40. The control unit 40 has an acquisition unit 42, an estimation unit 44, a power management unit 46, a presentation unit 48, and a peripheral equipment control unit 50. The power generation methods of the plurality of power generating elements 30a, 30b, 30c, 30d, and 30e may be different from one another.

In the embodiment, the power generating element 30a is an element for generating frictional power via the use of air exhaust or air intake from the electronic equipment 10, the power generating element 30b is an element for generating thermal power via the use of exhaust heat from the electronic equipment 10, and the power generating element 30c is an element for generating vibrational power via the use of vibrations of the electronic equipment 10. As such, the power generating elements 30a, 30b, and 30c generate power via the use of energy produced by operating the electronic equipment 10.

The power generating element 30d is an element for receiving light from within a room in which the electronic equipment 10 is installed to generate photoelectric power, and the power generating element 30e is an element for generating radio wave power via the use of radio waves in the 2.4 GHz band. The processing apparatus 20 may further include a power generating element of another power generation method. Hereinafter, the power generating elements 30a, 30b, 30c, 30d, and 30e in particular may simply be referred to as “power generating elements 30” when there is no need to distinguish therebetween.

The processing apparatus 20 includes a computer, where various functions are realized by the computer executing a program. The computer includes, as hardware, a memory into which the program is loaded, one or more processors for executing a loaded program, an auxiliary storage apparatus, another LSI, and the like. The processor is configured by a plurality of electronic circuits that includes a semiconductor integrated circuit or an LSI, and the plurality of electronic circuits may be mounted on one chip or may be mounted on a plurality of chips. The functional blocks illustrated in FIG. 2 are realized by the cooperation of hardware and software, and therefore, it will be understood by those skilled in the art that these functional blocks may be realized in various forms by hardware alone, software alone, or a combination thereof.

The processing apparatus 20 of the embodiment is not equipped with a secondary battery that is charged by an external power source, such as a commercial power source, or a primary battery. In the processing apparatus 20 of the embodiment, the plurality of power generating elements 30 has a power generating function, generating electric power used in the processing apparatus 20.

The power storage unit 32 is a capacitor, storing the power generated by the plurality of power generating elements 30.

The power management unit 46 is responsible for power management in the processing apparatus 20. For example, when a voltage of the power storage unit 32 reaches or exceeds a predetermined first threshold, the power management unit 46 supplies the power stored in the power storage unit 32 to various components in the processing apparatus 20 to activate various functions of the processing apparatus 20. By including the plurality of power generating elements 30, the processing apparatus 20 has the advantage of not needing to be equipped with a secondary or primary battery that is charged by an external power source.

The power management unit 46 supplies the power stored in the power storage unit 32 to an external charging target when the voltage of the power storage unit 32 reaches or exceeds a predetermined second threshold. Here, the second threshold is set to a value that is higher than that of the first threshold. There may be a plurality of charging targets, and an order of charging priority may be set in advance for the plurality of charging targets. For example, a charging target may be a built-in battery of the electronic equipment 10, may be the input device 14, or may be the HMD 12, and the order of charging priority may be set to the following order: the built-in battery of the electronic equipment 10, the input device 14, and the HMD 12. The power management unit 46 monitors an amount of charge (stored amount of power) in the charging target and, when the charge amount of the charging target falls below a predetermined amount, supplies the power stored in the power storage unit 32 to the charging target according to order of priority. For example, if a stored amount of power of the built-in battery of the electronic equipment 10 falls below the predetermined amount and, similarly, a charged amount of power of the input device 14 falls below a predetermined amount, the power management unit 46 charges the built-in battery of the electronic equipment 10 first according to the order of priority, then charges the input device 14. When a momentary power source interruption occurs in the electronic equipment 10, the power management unit 46 may, for example, supply power for saving game data to the electronic equipment 10.

The acquisition unit 42 acquires a generated amount of power generated via the use of energy produced by operating the electronic equipment 10. In the embodiment, the power generating element 30a generates frictional power via the use of air exhaust or air intake from the electronic equipment 10, the power generating element 30b generates thermal power via the use of exhaust heat from the electronic equipment 10, and the power generating element 30c generates vibrational power via the use of vibrations of the electronic equipment 10. The acquisition unit 42 may acquire the generated amount of power generated by each of the power generating elements 30a, 30b, and 30c. In addition, the acquisition unit 42 may acquire the generated amount of power generated by the respective power generating elements 30d and 30e. The amounts of power acquired may be a generated amount of power per unit of time, for example, a generated amount of power per hour.

The presentation unit 48 presents the user with generated amounts of power for each of the power generation methods. Specifically, the presentation unit 48 displays the generated amounts of power for each of the power generation methods on the display apparatus 34. Here, the presentation unit 48 may display on the display apparatus 34 a relationship between an amount of power consumed by the electronic equipment 10 and a total amount of power generated by the plurality of power generating elements 30.

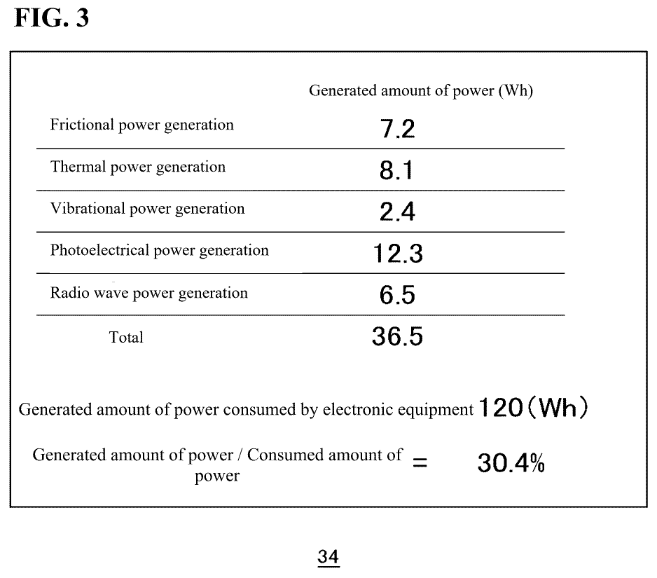

FIG. 3 illustrates a display example of generated amounts of power. The presentation unit 48 presents the respective generated amounts of power for each of the power generation methods, and also presents a ratio (recovery rate) of the total generated amount of power to the amount of power consumed by the electronic equipment 10. By being presented with the actual generated and consumed amounts of power, the user can be more conscious of saving energy.

The estimation unit 44 estimates a status of the electronic equipment 10 based on the generated amount of power acquired by the acquisition unit 42. The estimation unit 44 may detect a malfunction in the electronic equipment 10 based on a difference between an expected amount of generated power and the amount of generated power acquired by the acquisition unit 42. For example, the estimation unit 44 detects a malfunction in the electronic equipment 10 when the difference between the expected amount of generated power and the amount of generated power acquired by the acquisition unit 42 reaches or exceeds a predetermined threshold. The expected amount of generated power may be an average value of amounts of generated power acquired in the past, or may be an average value of amounts of generated power acquired in a most recent predetermined period (for example, a one month span).

If the amount of power generated by the power generating element 30a, which generates power via the use of air exhaust of the electronic equipment 10, is at or less than the expected amount of generated power by a first predetermined amount, the estimation unit 44 detects an insufficiency of the air exhaust, and estimates that a malfunction has arisen in a cooling fan. Here, the presentation unit 48 may display the possibility that a malfunction has arisen in the cooling fan on the display apparatus 34.

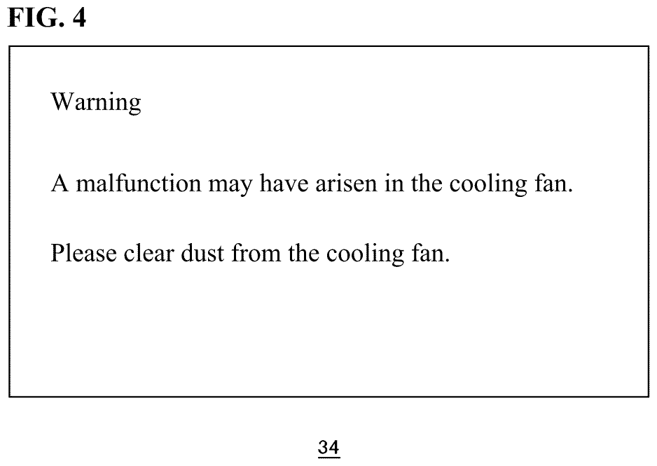

FIG. 4 illustrates an example of a warning display. The presentation unit 48 receives an estimation result via the estimation unit 44 and presents the warning, “A malfunction may have arisen in the cooling fan.”, to the user. Here, the presentation unit 48 presents the countermeasure, “Please clear dust from the cooling fan.”, to the user.

If the amount of power generated by the power generating element 30b, which generates power via the use of heat exhaust of the electronic equipment 10, is at or greater than the expected amount of generated power by the second predetermined amount, the estimation unit 44 detects the occurrence of overheating, and estimates that a malfunction has arisen in the cooling fan. Here, the presentation unit 48 displays the possibility that a malfunction has arisen in the cooling fan on the display apparatus 34. The display message may be similar to that illustrated in FIG. 4.

If the amount of power generated by the power generating element 30c, which generates power via the use of vibrations of the electronic equipment 10, is at or greater than the expected amount of generated power by a third predetermined amount, the estimation unit 44 detects that an issue has arisen in the attachment of a driving portion of a motor or the like within a housing, and estimates that rattling has arisen. Here, the presentation unit 48 may display, on the display apparatus 34, the possibility that rattling has arisen in the attachment of a component.

The above describes an example in which the estimation unit 44 detects a malfunction in the electronic equipment 10 based on the amount of generated power, however, the air exhaust and heat exhaust of the electronic equipment 10 vary depending on the game being run. For example, when the electronic equipment 10 runs a game that performs a high-speed computation to generate a high-resolution image, temperatures of the CPU and GPU tend to be relatively high, which readily increases the generated amount of power of the power generating element 30b. In such a case, the estimation unit 44 estimates that the user is concentrating on playing the game, and the peripheral equipment control unit 50 may receive a result of this estimation and, for example, gradually dim a light in the room in order to heighten a sense of immersion in the game for the user.

In addition, the estimation unit 44 may estimate that the electronic equipment 10 is not operating when there is no power generation arising from the electronic equipment 10. Here, in order to save energy, the peripheral equipment control unit 50 may generate a command to turn off a power source of the HMD 12 or the input device 14, and transmit the command to the HMD 12 or the input device 14. As such, the peripheral equipment control unit 50 may control a peripheral device according to an estimated status of the electronic equipment 10, thereby allowing for a heightened sense of immersion of the user in the game, as well as contributing to the saving of energy.

The above is a description of the present disclosure based on the embodiment. The embodiment is an example, and it will be understood by those skilled in the art that a variety of variations are possible in the combination of their respective constituent elements and respective processing processes, and that such variations are also within the scope of the present disclosure.

It is described in the embodiment that the processing apparatus 20 is not equipped with a secondary battery or a primary battery that is charged by an external power source, but in a modified example, the processing apparatus 20 may be equipped with a secondary battery and/or a primary battery that is charged by an external power source as an auxiliary power source. For example, the power management unit 46 may use power of the power storage unit 32 as long as the stored amount of power of the power storage unit 32 is not depleted, and may use an auxiliary power source when the stored amount of power of the power storage unit 32 is depleted.

The processing apparatus 20 in the embodiment is configured as a separate unit from the electronic equipment 10, but may also be built into the electronic equipment 10. In addition, although the processing apparatus 20 of the embodiment includes the power generating elements 30, the power generating elements 30 may be provided as separate units from the processing apparatus 20.

The power management unit 46 may include a configuration for increasing a power generation efficiency of each of the power generating elements 30. For example, the power management unit 46 may include a function of searching for two junction points having a large temperature difference in the electronic equipment 10 in order to increase the power generation efficiency of the power generating element 30b for generating thermal power. In addition, the power management unit 46 may include a function of automatically adjusting an orientation of the power generating element 30d in order to increase the power generation efficiency of the power generating element 30d for performing photoelectric power. In addition, the power management unit 46 may include a function of automatically positioning the antenna in a location having high radio wave reception efficiency in order to enhance the power generation efficiency of the power generating element 30e for performing radio wave power.

The present disclosure may be used in a field of art for estimating the status of electronic equipment.

### Description of Reference Numerals

1 . . . Information processing system, 10 . . . electronic equipment, 12 . . . HMD, 14 . . . input device, 20 . . . processing apparatus, 30a, 30b, 30c, 30d, 30e . . . power generating element, 32 . . . power storage unit, 34 . . . display device, 40 . . . control unit, 42 . . . acquisition unit, 44 . . . estimation unit, 46 . . . power management unit, 48 . . . presentation unit, 50 . . . peripheral equipment control unit.

1. A processing apparatus for estimating a status of an electronic equipment for executing an application, the processing apparatus comprising:
an acquisition unit for acquiring a generated amount of power generated via the use of energy produced by operating the electronic equipment; and
an estimation unit for estimating the status of the electronic equipment based on the generated amount of power acquired.

2. The processing apparatus according to claim 1, wherein the acquisition unit acquires generated amounts of power generated by a plurality of power generating elements that use different power generation methods.

3. The processing apparatus according to claim 2, further comprising a presentation unit for presenting the generated amounts of power for each of the power generation methods.

4. The processing apparatus according to claim 3, wherein the presentation unit presents a relationship between an amount of power consumed by the electronic equipment and a total amount of power generated by the plurality of power generating elements.

5. The processing apparatus according to claim 1, wherein the estimation unit detects a malfunction in the electronic equipment based on a difference between an expected amount of generated power and the generated amount of power acquired by the acquisition unit.

6. The processing apparatus according to claim 1, further comprising a peripheral equipment control unit for controlling a peripheral device according to the estimated status of the electronic equipment.

7. The processing apparatus according to claim 1, further comprising: a power storage unit for storing the generated power; and a power management unit for supplying power to a charging target based on a priority order.

8. A computer-implemented method for estimating a status of an electronic equipment for executing an application, comprising:
acquiring a generated amount of power generated via the use of energy produced by operating the electronic equipment; and
estimating the status of the electronic equipment based on the generated amount of power acquired.

9. The method of claim 8, comprising acquiring generated amounts of power generated by a plurality of power generating elements that use different power generation methods.

10. The method of claim 9, comprising presenting the generated amounts of power for each of the power generation methods.

11. The method of claim 10, comprising presenting a relationship between an amount of power consumed by the electronic equipment and a total amount of power generated by the plurality of power generating elements.

12. The method of claim 8, comprising detecting a malfunction in the electronic equipment based on a difference between an expected amount of generated power and the generated amount of power acquired by the acquisition unit.

13. The method of claim 8, comprising controlling a peripheral device according to the estimated status of the electronic equipment.

14. The method of claim 8, comprising storing the generated power; and a power management unit for supplying power to a charging target based on a priority order.

15. A non-transitory computer-readable medium that stores instructions which, when executed by one or more computer processors, causes the one or more computer processors to perform operations comprising:
acquiring a generated amount of power generated via the use of energy produced by operating the electronic equipment; and
estimating the status of the electronic equipment based on the generated amount of power acquired.

16. The medium of claim 15, comprising acquiring generated amounts of power generated by a plurality of power generating elements that use different power generation methods.

17. The medium of claim 16, comprising presenting the generated amounts of power for each of the power generation methods.

18. The medium of claim 17, comprising presenting a relationship between an amount of power consumed by the electronic equipment and a total amount of power generated by the plurality of power generating elements.

19. The medium of claim 15, comprising detecting a malfunction in the electronic equipment based on a difference between an expected amount of generated power and the generated amount of power acquired by the acquisition unit.

20. The medium of claim 15, comprising controlling a peripheral device according to the estimated status of the electronic equipment.
